(19) United States
(12) Patent Application Publication
(10) Pub. No.: US 2010/0201291 A1
(43) Pub. Date: Aug. 12, 2010

(54) MULTI-ELEMENT PIEZOELECTRIC ACTUATOR DRIVER

(76) Inventors: Michael C. CHEIKY, Thousand Oaks, CA (US); Michael N. DIAMOND, Thousand Oaks, CA (US)

Correspondence Address: SHEPPARD, MULLIN, RICHTER & HAMPTON LLP, 12275 EL CAMINO REAL, SUITE 200, SAN DIEGO, CA, 92130, US

(21) Appl. No.: 12/686,247

(22) Filed: Jan. 12, 2010

Related U.S. Application Data
(60) Provisional application No. 61/144,274, filed on Jan. 13, 2009.
(60) Provisional application No. 61/144,254, filed on Jan. 13, 2009.

(51) Int. Cl. H02N 2/06; H01L 41/04

(52) U.S. Cl. 318/116; 310/366

(57) ABSTRACT

A multi-element piezoelectric actuator and driver is presented that allows greater control over the dynamic displacement response of a piezoelectric actuator. A system comprises a piezoelectric driving apparatus configured to transmit a plurality of waveform signals to a corresponding plurality of piezoelectric elements of a piezoelectric actuator. The piezoelectric driving apparatus comprises a waveform generator to generate a waveform configured to operate a piezoelectric element, a plurality of channels coupled to the waveform generator and configured to be electrically coupled the piezoelectric elements of the piezoelectric actuator, a channel comprising an input configured to receive a waveform, a driving amplifier electrically coupled to the input and configured to amplify the waveform, and an output configured to transmit the waveform and configured to be electrically coupled to a piezoelectric element.

### CROSS-REFERENCE TO RELATED APPLICATIONS

This application claims priority from U.S. Provisional Patent Application Ser. Nos. 61/144,274 filed Jan. 13, 2009, and claims priority from U.S. Provisional Patent Application Ser. Nos. 61/144,254 filed Jan. 13, 2009, each which is hereby incorporated herein by reference in its entirety.

### TECHNICAL FIELD

The present invention relates to piezoelectric devices, and more particularly, some embodiments relate to piezoelectric actuators.

### DESCRIPTION OF THE RELATED ART

Piezoelectric actuators comprise a piezoelectric element such as a piezoelectric material (e.g., a crystal, ceramic, or polymer) coupled to electrical contacts to allow a voltage to be applied to the piezoelectric material. Piezoelectric actuators utilize the converse piezoelectric effect to create a mechanical displacement in response to an applied voltage. Such actuators may be used in applications such as machine tools, disk drives, military applications, ink delivery systems for printers, medical devices, precision manufacturing, fuel injection, or any application which requires high precision or high speed fluid delivery.

In most actuators, a single piezoelectric element is used to mechanically actuate the device. While a single-element piezoelectric actuator can precisely control the total actuator displacement, the actual displacement path followed to reach the total displacement is difficult to control. When a driving voltage is applied to a single piezoelectric element, the displacement response is often not linear with respect to the applied voltage. For example, the physical effects of static or dynamic friction, or the nature of the piezoelectric material itself may prevent the actuator from responding linearly according to an applied voltage.

### BRIEF SUMMARY OF EMBODIMENTS OF THE INVENTION

According to various embodiments of the invention a multi-element piezoelectric actuator and driver is presented that allows greater control over the dynamic displacement response of a piezoelectric actuator.

One embodiment of the invention features a system comprising a piezoelectric driving apparatus configured to transmit a plurality of waveform signals to a corresponding plurality of piezoelectric elements of a piezoelectric actuator. The piezoelectric driving apparatus comprises (i) a waveform generator to generate a waveform configured to operate a piezoelectric element, (ii) a plurality of channels coupled to the waveform generator and configured to be electrically coupled to the piezoelectric elements of the piezoelectric actuator, (iii) a channel comprising an input configured to receive a waveform, (iv) a driving amplifier electrically coupled to the input and configured to amplify the waveform, and (v) an output configured to transmit the waveform and configured to be electrically coupled to a piezoelectric element.

According to some embodiments of the invention, the piezoelectric driving apparatus further comprises a conditioner electrically coupled to the waveform generator, and configured to isolate a portion of the waveform and to transmit the isolated portion to at least one of the channels.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 illustrates an example of embodiment of a piezoelectric actuator having a plurality of piezoelectric elements according to an embodiment of the invention.

FIG. 2 illustrates an example actuator displacement resulting from an example waveform according to an embodiment of the invention.

FIG. 3 is a functional block diagram illustrating a system having a piezoelectric driver coupled to a multi-element piezoelectric actuator according to an embodiment of the invention.

FIG. 4 is a functional block diagram of an example embodiment of a multi-element piezoelectric driver system having a plurality of waveform generators.

FIG. 5 illustrates an example three-element piezoelectric actuator driver according to an embodiment of the invention.

FIG. 6a is a block circuit diagram illustrating an offset and clip circuit block according to an embodiment of the invention.

FIG. 6b illustrates the effects of the circuit described in FIG. 6a on an illustrative waveform.

FIG. 7a is a block circuit diagram illustrating an alternative offset and clip circuit block according to an embodiment of the invention.

FIG. 7b illustrates the effects of the circuit described in FIG. 7a on an illustrative waveform.

FIG. 8 is a functional block diagram illustrating a digital implementation of a multi-element piezoelectric actuator and driver according to an embodiment of the invention.

FIG. 9 illustrates a switching amplifier that may be employed in some embodiments of the invention.

FIG. 10 is a functional block diagram illustrating a configuration that scales system parameters as a high voltage source is modified according to an embodiment of the invention.

FIG. 11 illustrates an exemplary computing module, which may be used to implement various components in particular embodiments of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

Before describing the invention in detail, it is useful to describe an example environment with which the invention can be implemented. One such environment comprises a system requiring high speed or high precision fluid delivery. Another example is a fuel injector for fuel delivery to a combustion chamber of an engine.

Another such environment is a piezoelectric actuator driver of the type described in U.S. patent application Ser. No. 12/652,679, which is herein incorporated by reference in its entirety. Further environments may employ piezoelectric actuator drivers of these types and a fault recovery system of the type described in U.S. patent application Ser. No. 12/652,681, which is hereby incorporated by reference in its entirety. Another environment is system for defining a piezoelectric actuator waveform of the type described in U.S. patent application Ser. No. 12/652,674, which is hereby incorporated by reference in its entirety.

Another environment is a fuel injector for fuel delivery to a combustion chamber of an engine. For example, the fuel injector may be a fuel injector for dispensing fuel into a combustion chamber of an internal combustion engine, wherein injector pressure is high enough that the fuel charge operates as a super-critical fluid. An example of this type of fuel injector is disclosed in U.S. Pat. No. 7,444,230, herein incorporated by reference in its entirety.

Another example is a piezoelectrically actuated fuel injector, for example, of the type disclosed in U.S. Provisional patent application Ser. No. 12/503,764, filed on Jul. 15, 2009, having a piezoelectrically actuated injector pin having a heated portion and a catalytic portion; and a temperature compensating unit; wherein fuel is dispensed into a combustion chamber of an internal combustion engine.

From time-to-time, the present invention is described herein in terms of these example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this section prevails over the definition that is incorporated herein by reference.

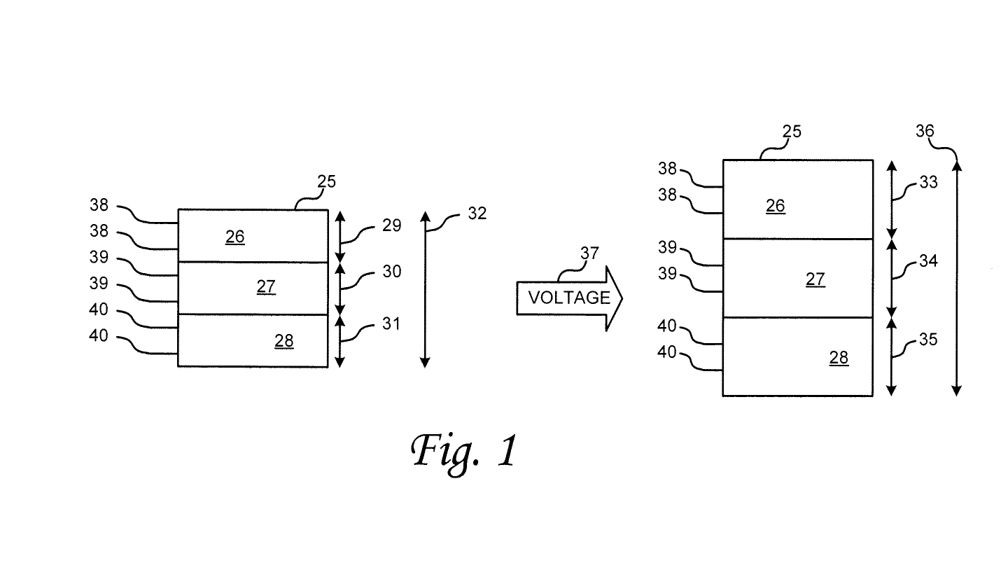

FIG. 1 illustrates a piezoelectric actuator having a plurality of piezoelectric elements according to an embodiment of the invention. Multi-element piezoelectric actuator 25 has a plurality of piezoelectric elements 26, 27, 28 connected in series. Each piezoelectric element has a corresponding rest displacement 29, 30, and 31, resulting in a total rest displacement 32. Piezoelectric elements 26, 27, and 28 may comprise a piezoelectric material, such as a piezoelectric crystal or a piezoelectric ceramic. Piezoelectric elements 26, 27, and 28 further comprise electrical contacts 38, 39, and 40, respectively. When a voltage 37 is applied to the electrical contacts, the individual piezoelectric elements expand to displacements 33, 34, and 35, respectfully, resulting in an excited displacement 36 that is greater than the rest displacement 32. Some embodiments may be configured to allow the piezoelectric elements to be operated independently of one another. For example, a voltage could be applied only to contacts 38, causing only piezoelectric element 26 to expand. In further embodiments, the voltage applied to the contacts varies as a function of time, causing the actuator displacement to also vary as a function of time.

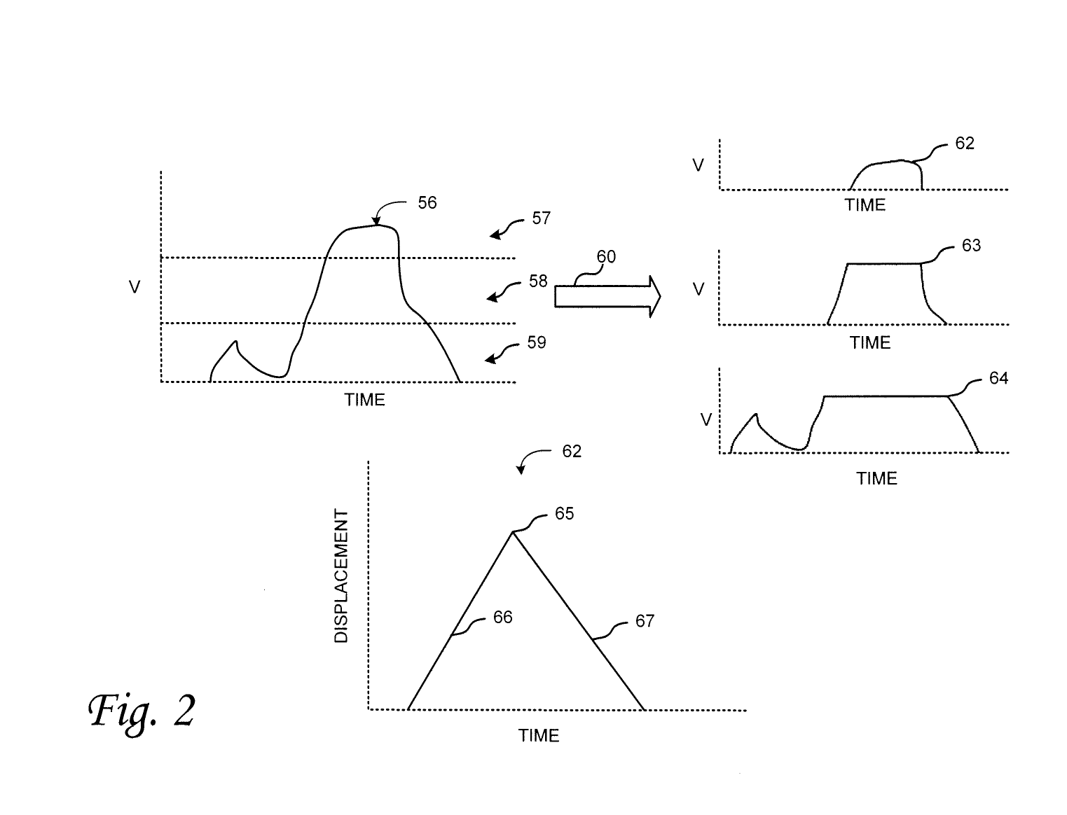

FIG. 2 illustrates an example actuator displacement resulting from an example waveform according to an embodiment of the invention. In some embodiments of the invention, an actuator may have a desired behavior 62. For example, an engine's performance may be improved if the actuator in a piezoelectrically actuated fuel injector displaces according to a particular function of time. In the illustrated example of a desired behavior 62, the desired actuator displacement follows a contour 65 that is linearly increasing with respect to time for contour portion 66, and is linearly decreasing with respect to time for a contour portion 67. However, in physical properties of an actuator, such as static and kinetic friction, flue effect, non-linear piezoelectric material response to voltage, and non-linear amplifier performance, prevent the actuator from having a linear displacement response to input voltage.

In order to obtain such a desired actuator displacement function 65, a voltage waveform 56 may be generated. Waveform 56 may have a contour that is predetermined to compensate for the physical properties of the actuator to obtain the desired actuator behavior. The illustrated example waveform 56 has a contour that is arbitrarily chosen for purposes of illustration only. To drive the individual piezoelectric elements of a multi-element piezoelectric actuator, portions 57, 58, and 59 of waveform 56 are isolated. These isolated wave portions may then be individually transmitted 60 to the individual elements of the piezoelectric actuator as waveforms 62, 63, and 64. In other embodiments, the individual element waveforms 62, 63, and 64 may be calculated and generated individually. In some embodiments, the isolated wave portions 57, 58, and 59 may be determined so that each piezoelectric element displaces an equal distance. In other embodiments, the wave portions 57, 58, 59, may be determined according to other considerations. For example, a three-element piezoelectric actuator may have a maximum displacement of 0.12 mm, each element having a maximum displacement of 0.04 mm. If the actuator were to displace a total of 0.09 mm, in some embodiments the wave portions may be chosen so that each piezoelectric element displaces 0.03 mm. In other embodiments, the wave portions may be chosen so that the first two piezoelectric elements displace 0.04 mm and the third element displaces the remaining 0.01 mm, for example to increase the operating life of the actuator.

In some embodiments, voltage waveform 56 may be calculated directly from first principles and the desired displacement function 65. In other embodiments, voltage waveform 56 may be determined using a method such as the iterative tuning method described in copending U.S. patent application Ser. No. 12/652,674, the contents of which are hereby incorporated by reference in its entirety. In some embodiments, physical or other considerations may prevent an ideal desired actuator behavior from being obtained. In these embodiments, voltage waveform 56 may be determined to allow the actual actuator behavior to approximate the desired actuator behavior 65, within the constraints of the system. For example, a three-element actuator may not be able to realize a completely linear displacement behavior. The waveform 56 or waveforms 62, 63, and 64 may then be determined to cause the actuator to have a substantially linear displacement behavior. In further embodiments, a particular waveform may be determined for each actuator used in a system. For example, an individual waveform may be determined for each actuator used in an engine fuel injection system. In other embodiments, a waveform may be determined that is applied to a class or group of actuators. For example, a particular waveform may be determined for an entire class of four-element gallium orthophosphate actuators. In these embodiments, a waveform, or plurality of waveforms, may be determined that substantially approximate the desired actuator behavior within the normal range of physical properties of the class or group of actuators.

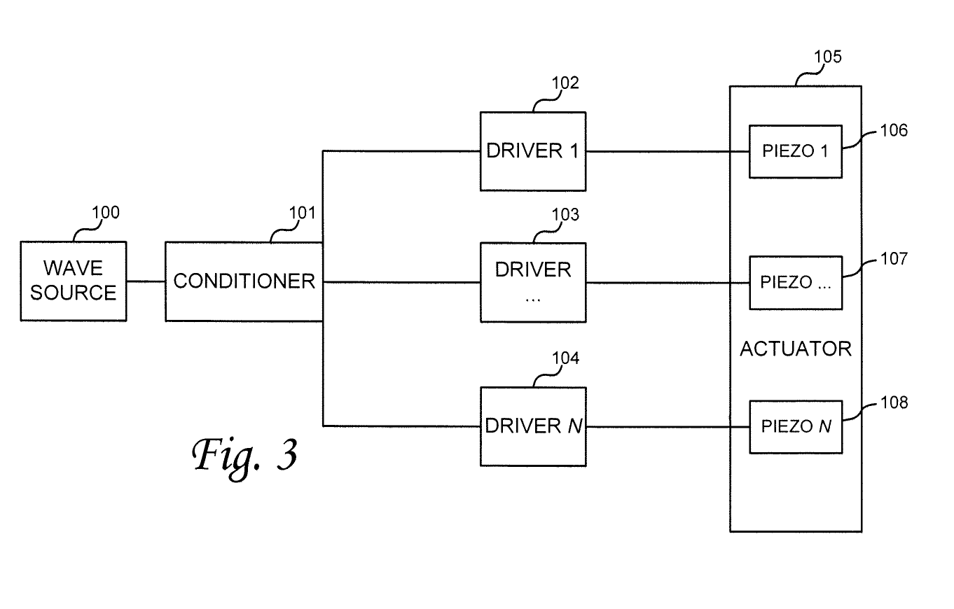

FIG. 3 is a functional block diagram illustrating a system having a piezoelectric driver coupled to a multi-element piezoelectric actuator according to an embodiment of the invention. A wave source 100 is coupled to a conditioner 101 and is configured to provide a waveform to conditioner 101. Wave source 100 may comprise any tool or device used to generate an electrical signal wave, for example an analog waveform generator such as a function generator or an arbitrary waveform generator, or a digital waveform generator. Conditioner 101 is coupled to plurality of drivers 102, 103, and 104. Conditioner 101 is configured to provide selected portions of the waveform to the plurality of drivers. Conditioner 101 may comprise any tool or device used to apportion or divide a voltage source or waveform, for example a parallel-connected group of offsetting and clipping circuits as described herein, or a digital signal processing implementation of a waveform divider. The plurality of drivers 102, 103, and 104, are coupled to the piezoelectric elements 106, 107, and 108, respectively, of multi-element piezoelectric actuator 105 and are configured to provide the required drive voltages to their respective piezoelectric elements. Drivers 106, 107, and 108, may comprise, for example linear amplifiers or switching amplifiers.

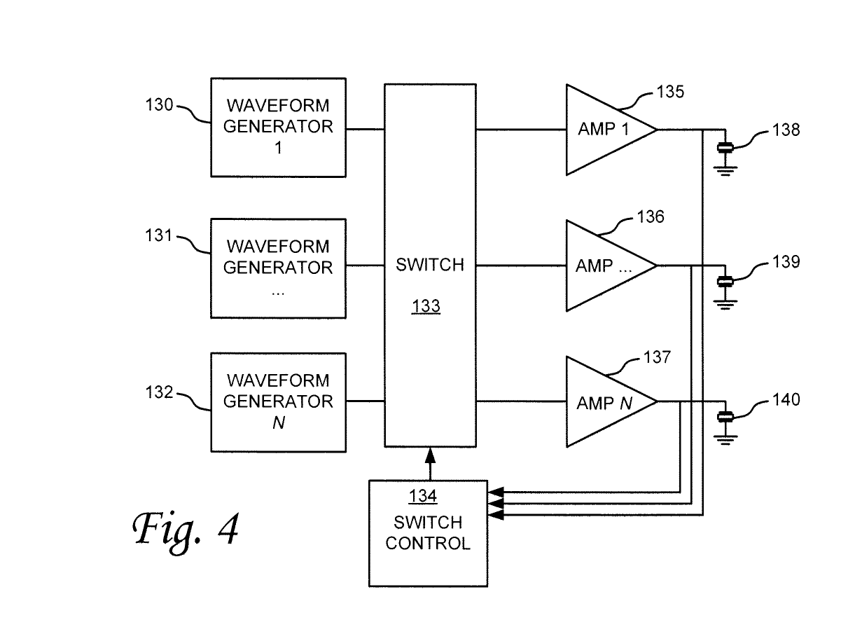

FIG. 4 is a functional block diagram of an example embodiment of a multi-element piezoelectric driver system having a plurality of waveform generators. Plurality of waveform generators 130, 131, 132, are coupled to a switch 133 and are configured generate waveforms for operating piezoelectric elements 138, 139, and 140 of a piezoelectric actuator. Switch 133 is coupled to amplifiers 135, 136, and 137 and switch control module 134. Switch 133 is configured to transmit the waveforms received from the plurality of waveform generators to the various amplifiers as controlled by the switch control 134. Switch control 134 is configured to monitor conditions on the lines connecting amplifiers 135, 136, and 137 to piezoelectric elements 138, 139, and 140. Switch 133 may comprise, for example, an analog switch matrix or a digital implementation thereof coupled to a digital to analog converter and switch control 134 may comprise, for example, a microprocessor programmed to control the switch. Amplifiers 135, 136, and 137 are coupled to corresponding piezoelectric elements 138, 139, and 140 and are configured to receive transmitted waveforms from switch 133 and to amplify them to drive the piezoelectric elements. Amplifiers 135, 136, and 137, may comprise any amplifier, such as a linear or switching amplifier.

Switch 133 and switch control 134 may operate according to the method disclosed in U.S. patent application Ser. No. 12/652,681, the contents of which are hereby incorporated by reference in its entirety, to allow the embodiment to continue to operate in the event that one or more of the piezoelectric elements 138, 139, or 140 fail. For example, if the monitored voltage to piezoelectric element 138 were to suddenly drop, switch control 134 could command switch 133 to prevent the waveform from waveform generator 130 from being transmitted to amplifier 135. Or, if the waveform contributed more to a desired actuator behavior, the switch control 134 may use the switch 133 to route the waveform to another amplifier and to cease transmitting a less contributing waveform.

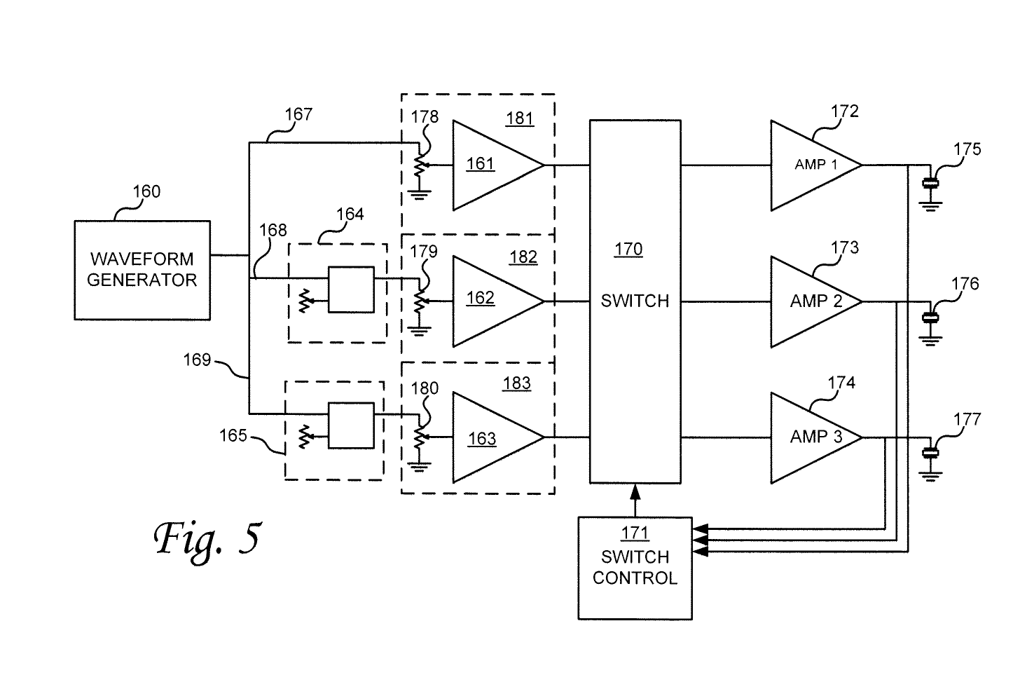

FIG. 5 illustrates an example three-element piezoelectric actuator driver according to an embodiment of the invention. In particular, a waveform generator 160 is configured to provide a waveform for driving a three-element piezoelectric actuator using a waveform division method as described herein. Waveform generator 160 transmits the generated waveform along three parallel channels 167, 168, and 169. The waveform is portioned or divided in the channels, and the waveform portions are amplified using amplifiers 172, 173, and 174 and are used to drive piezoelectric elements 175, 176, and 177.

The first channel 167 comprises an amplifier circuit 181 comprising, for example a potentiometer 178 and an amplifier 161. Amplifier circuit 181 is configured to receive the waveform and to modify it into a waveform portion configured to drive an individual element of the piezoelectric actuator. For example, amplifier circuit 181 may amplify the waveform such that the waveform portion reaches its peak power when the received waveform reaches a predetermined voltage level, for example, approximately ⅓ of its peak voltage. The amplifier circuit 181 may be further configured to allow the predetermined voltage level to be varied depending on the particular actuator application. For example, in a fuel injector application, the predetermined voltage level may be modified, as described in U.S. patent application Ser. No. 12/652,674, to produce the desired engine performance.

The second channel 168 comprises an offset and clip circuit 164, and an amplifier circuit 182. Offset and clip circuit 164 is coupled to the waveform generator and the amplifier circuit 182, and is configured to receive the waveform from the waveform generator and to truncate or clip it by removing the bottom portion of the waveform. In some embodiments, the removed portion corresponds to the wave portion transmitted by the first channel amplifier circuit. For example, if the first channel transmitted a wave portion corresponding to the bottom ⅓ of the waveform, then the clipping level may be set to remove the bottom ⅓ of the waveform. In further embodiments, the clipping level is adjustable, and is configured to be varied depending on the particular actuator application. For example, in a fuel injector application, the clipping level may be modified as described in U.S. patent application Ser. No. 12/652,674, to produce the desired engine performance. Amplifier circuit 182 may comprise, for example, potentiometer 179 and amplifier 162. Amplifier circuit 182 is configured to amplify the clipped waveform so that a portion of the clipped waveform is transmitted to a piezoelectric actuator. For example, if the first channel's waveform portion corresponds to the lower ⅓ of the waveform, and the clipping circuit clipped the bottom ⅓ of the waveform, then the amplifier circuit 182 may amplify the clipped waveform so that the lower ½ of the clipped waveform is transmitted (corresponding to the middle ⅓ of the original waveform). In further embodiments, the amplifier circuit may also be adjusted to amplify different portions of the clipped waveform, according to the actuator's use.

The third channel 169 comprises an offset and clip circuit 165 and an amplifier circuit 183. Offset and clip circuit 165 is coupled to the waveform generator and the amplifier circuit 183, and is configured to receive the waveform from the waveform generator and to truncate or clip it by removing the bottom portion of the waveform. In some embodiments, the removed portion corresponds to the wave portions transmitted by the first and second channels. For example, if the first channel and second channel transmitted wave portions corresponding to the bottom ⅔ of the waveform, then the offset and clip circuit may be configured clip the waveform at ⅔ of its maximum voltage. In further embodiments, the clipping level is adjustable, and is configured to be varied depending on the particular actuator application. For example, in a fuel injector application, the clipping level may be modified as described in U.S. patent application Ser. No. 12/652,674, to produce the desired engine performance. Amplifier circuit 183 may comprise, for example, potentiometer 180 and amplifier 163. Amplifier circuit 183 is configured to amplify the clipped waveform so that a portion of the clipped waveform is transmitted to a piezoelectric actuator. For example, if the first channel and second channel transmitted the lower two portions of the waveform, then the amplifier circuit 183 may amplify the clipped waveform so that the entire clipped waveform is transmitted (corresponding to the upper ⅓ of the original waveform). In further embodiments, the amplifier circuit may also be adjusted to amplify different portions of the clipped waveform, according to the actuator's use.

Switch 170 is coupled to the channels 167, 168, and 169, the output amplifiers 172, 173, and 174, and the switch control 171. Switch 170 is configured to route any input channel 167, 168, or 169, to any output amplifier 172, 173, or 174, or to disable any input channel, for example, by connecting it to ground. Switch 170 may comprise, for example, an analog switch matrix, or a plurality of relays. Switch control 171 is coupled to switch 170 and is configured to monitor the lines connecting the output amplifiers 172, 173, and 174. Switch control 171 is further configured to reroute which waveform portion is transmitted to which output amplifier if the monitored conditions indicate that a piezoelectric elements 175, 176, or 177 has failed. For example, switch control 171 and switch 170 may operate according to the method described in U.S. patent application Ser. No. 12/652,681 to allow the actuator to continue to operate in the event that one or more of the piezoelectric elements 175, 176, or 177 fail. Amplifiers 172, 173, and 174 are configured to receive waveform portions routed through the switch 170 and to drive them to enable operation of piezoelectric elements 175, 176, and 177. Amplifiers 172, 173, and 174, may comprise any power amplifier, for example linear or switching-type amplifiers.

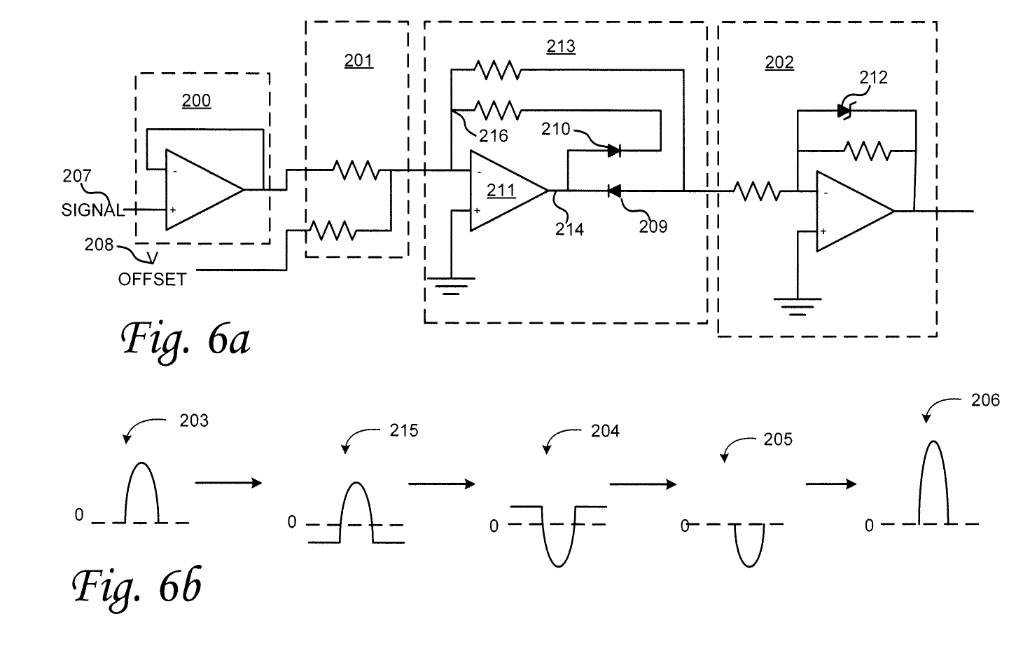

FIG. 6a is a block circuit diagram illustrating an offset and clip circuit block according to an embodiment of the invention. FIG. 6b illustrates the effects of the circuit described in FIG. 6a on an illustrative waveform. Buffer 200 is configured to receive a voltage waveform signal 207 and to provide the waveform 203 with a low source impedance to the rest of the offset and clip circuit. Offset portion 201 is coupled to the buffer 200, to an offset voltage 208 and to clipping portion 213. Offset voltage 208 is chosen to offset the waveform 203 so that 0 volts corresponds to the predetermined clipping level, to produce the offset waveform 215. Offset waveform 215 is transmitted to clipping portion 213. Clipping portion 213 may comprise an operational amplifier configured as an inverting amplifier in the manner illustrated. Offset waveform is inverted by operational amplifier 211, to produce an inverted offset waveform 204 at point 214. The positive and negative voltage portions of inverted offset waveform 204 are separated using diodes 210 and 209 as shown. The separated portions are rejoined at point 216 to provide the full waveform to the inverting amplifier. The negative portion 205 of the inverted and offset waveform 204 is connected to amplifying portion 202. Amplifying portion 202 may comprise another operational amplifier in an inverting amplifier configuration as illustrated. Amplifying portion 202 produces and transmits a re-inverted and amplified waveform 206 for further use in the actuator driver. In some embodiments, a zener diode 212 may be added to the inverting amplifier portion configuration to allow the amplifier 202 to allow the amplifier to remain in its linear operating range (i.e. to avoid saturation).

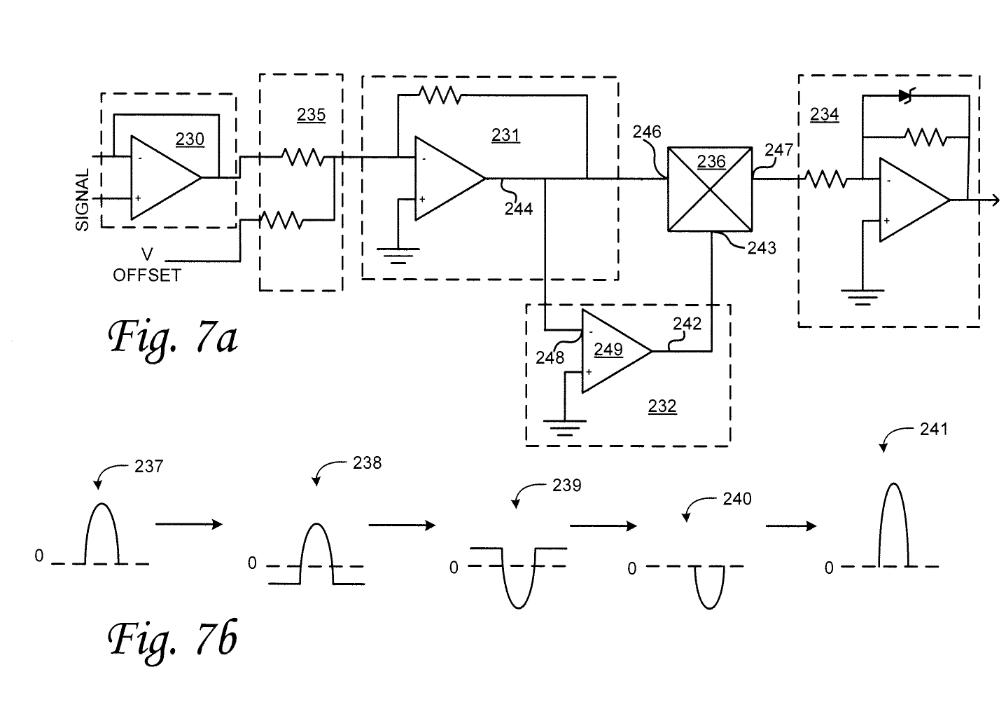

FIG. 7a is a block circuit diagram illustrating an alternative offset and clip circuit block according to an embodiment of the invention. FIG. 7b illustrates the effects of the circuit described in FIG. 7a on an illustrative waveform. Buffer 230 provides a signal waveform 237 having a low source impedance to offset portion 235. Offset portion 235 is coupled to the buffer 230, an offset voltage, and inverting amplifier 231. Offset portion 235 offsets the waveform 237 by a predetermined voltage corresponding to a desired clipping level to produce offset waveform 238. Offset waveform 238 is provided to inverting amplifier 231. The output 244 of inverting amplifier 231 is coupled to the negative voltage input of a voltage comparator 232 and an input contact 246 of switch 236, for example to the inverting input 248 of operational amplifier 249 in a voltage comparator configuration, and a contact 246 of an analog switch 236. The output 242 of voltage comparator 232 is coupled to the control terminal 243 of switch 236. Inverting amplifier 231 inverts offset waveform 238 to produce an inverted offset waveform 239 and to simultaneously provide it to comparator 232 and switch 236. Comparator 232 is configured to compare the inverted and offset waveform 239 to ground, so that comparator 232 produces a high voltage output when the inverted and offset waveform 239 has a negative voltage. This high voltage output causes switch 236 to conduct between input contact 246 and output contact 257. Accordingly, when the inverted and offset waveform 239 has a negative voltage, it is conducted to output contact 247, and when the inverted offset waveform 239 has a positive voltage it is not conducted. Output contact 247 therefore provides a clipped waveform 240 to inverted and amplifier portion 234. Inverted and amplifier portion 234 operates as described herein to provide waveform 241 for further use in operating an actuator element. In further embodiments, the function of analog switch 236 may be implemented in an analog switch matrix, for example, as described with respect to FIG. 5, thereby reducing the total number of needed analog switches.

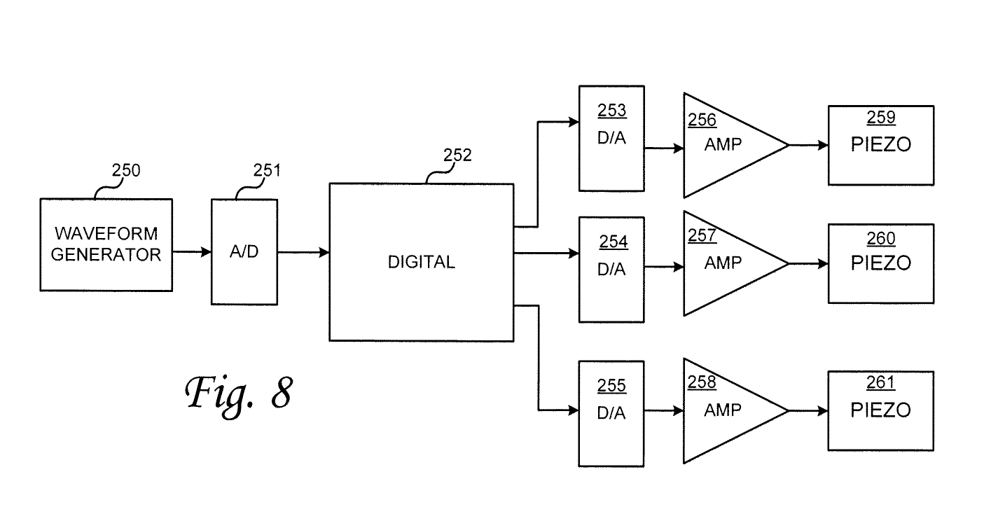

FIG. 8 is functional block diagram illustrating a digital implementation of a multi-element piezoelectric actuator and driver according to an embodiment of the invention. Waveform generator 250 outputs an analog voltage waveform to an analog to digital converter 251. Analog to digital converter 251 outputs the digitally converted waveform to microprocessor 252. Microprocessor 252 is programmed to perform the functions of dividing the digital waveform in to digital waveform portions for individual operations of piezoelectric elements 260. Microprocessor is further programmed to output each digital waveform portion to digital to analog converters 253, 254, and 255. Each digital to analog converter 253, 254, and 255 converts its respective digital waveform portion into an analog waveform portion, which is then outputted to power amplifiers 256, 257, and 258. Power amplifiers 256, 257, and 258 amplify the received waveform portions to drive a piezoelectric element and output the amplified waveform portions to piezoelectric elements 259, 260, and 261, respectively. In further embodiments, the functions of waveform generator 250 may be digitally implemented, so that microprocessor 252 may be programmed to produce a digital waveform, or digital waveform portions, directly. In still further embodiments, microprocessor 252 may be configured to monitor the piezoelectric elements 259, 260, and 261, and may be configured to provide fault control, for example through the methods described in U.S. patent application Ser. No. 12/652,681. In yet further embodiments, an integrated circuit embodying digital logic to perform the functions of microprocessor 252 may be used in place of microprocessor 252.

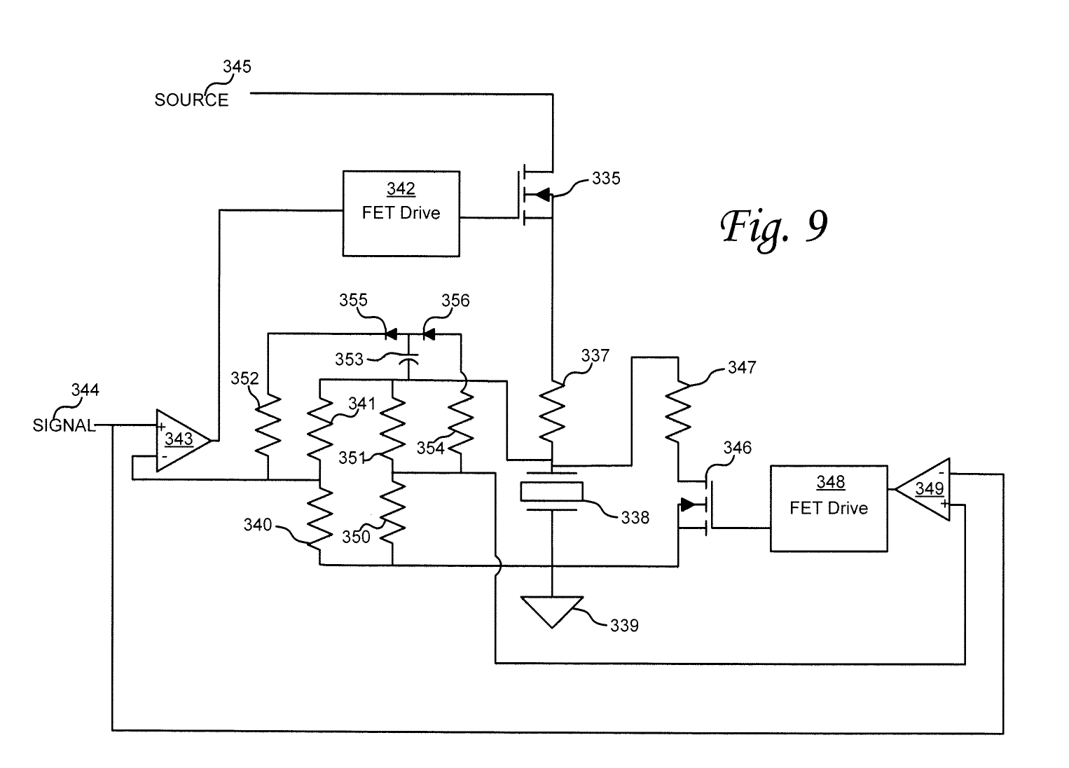

FIG. 9 illustrates a switching amplifier that may be employed in some embodiments of the invention. For example, a circuit of the type illustrated in FIG. 9 may serve as any, or all, of amplifiers 172, 173, or 174, as described with respect to FIG. 5. The switching amplifier circuit causes the voltage across piezoelectric element 338 to track the signal 344 by connecting and disconnecting the piezoelectric element to a source voltage 345 having a predetermined DC voltage sufficient to cause the piezoelectric element to actuate. A switch 335 is configured to switchably connect and disconnect voltage source 345 to piezoelectric element 338. In some embodiments, the switch is a field effect transistor (FET) 335 configured to act as a switch controlled by the FET driver 342. As illustrated, a comparator 343 is configured to compare the voltage across the piezoelectric element 338 with a signal voltage 344. For example, the comparator 343 may be an operational amplifier configured as a voltage comparator, or a dedicated voltage comparator. In some embodiments, scaling resistors 341 and 340 are provided. The resistances of the scaling resistors may be chosen to scale the voltage across the piezoelectric element to an appropriate level for comparison with the signal.

The comparator 343 is configured such that when the voltage of the signal 344 is greater than the voltage across the piezoelectric element 338, the comparator 343 connects the voltage source 345 to the piezoelectric element 338 using the switch 335 and FET driver 342. The piezoelectric element has a capacitance, and acts as a capacitor in the circuit. When the voltage source 345 is connected to the piezoelectric element 338, the voltage across the element rises, causing the element to actuate. When the voltage across the element rises above the voltage of the signal, the comparator switches the switch 335 to disconnect the voltage source 345. When the voltage source 345 is disconnected, the voltage across the element remains constant, until the signal is again higher than the voltage across the element, again causing the element to actuate. Accordingly, the illustrated circuit causes the voltage across the piezoelectric element to track the rising portion of a signal voltage, thereby causing the piezoelectric element to actuate in response to the signal.

In further embodiments, a current limiter, such as current limiting resistor 337 may be provided to limit the amount of current flowing through the circuit. The rate of voltage increase across the piezoelectric element 338 will depend on the voltage of the voltage source 345, the voltage across the element, and the resistance of the current limiting resistor 337. In particular embodiments, the source voltage 345 and the resistance of the current limiting resistor 337 are chosen such that the rate of voltage increase across the piezoelectric voltage exceeds the rate of voltage change of the signal 344. In these embodiments, the voltage change across the piezoelectric element does not lag behind the voltage change of the signal.

The circuit illustrated in FIG. 9 further comprises a discharging portion. A second switch, for example, FET 346 and FET driver 348, is configured to switchably connect and disconnect the piezoelectric element 338 to the ground 339. A second comparator 349 is configured to compare the signal voltage 344 with the voltage across the piezoelectric element 338. The second comparator 349 uses the switch to connect the element 338 to the ground when the voltage across the piezoelectric element 338 is greater than the signal voltage 344. The second comparator 349 disconnects the piezoelectric element 338 from the ground when the voltage across the piezoelectric element 338 is less than the signal voltage 344. Accordingly, the voltage across the piezoelectric element tracks the signal voltage as the signal voltage drops, and the piezoelectric element contracts in response. The rate of voltage drop across the piezoelectric element 338 is a function of the element's capacitance and the resistance between the element and ground. Accordingly, a resistor 347 may be included in the circuit to control the rate of voltage discharge across the piezoelectric element. In further embodiments, the circuit can be configured so that both switches are prevented from activating simultaneously. For example, a time delay and logic circuitry can be added that prevents one switch from activating for the time the other switch is active plus the time delay.

Scaling resistors 351 and 350 scale the voltage compared to the signal by comparator 349 to an appropriate level for comparison with the signal. In some embodiments, the resistance of scaling resistors 351 and 350 may be chosen to be different than that of scaling resistors 341 and 340. In these embodiments, the voltage across the piezoelectric element 338 is scaled differently for input into comparator 343 and comparator 348.

In a particular embodiment, resistor 341 has a resistivity of about 182 kΩ and resistor 340 has a resistivity of about 7.5 kΩ. This results in the comparator 343 comparing the signal voltage 344 with a voltage equal to 7.5/(182+7.5)=3.96% of the voltage across piezoelectric element 338. In this embodiment, resistor 351 has a resistivity of about 200 kΩ and resistor 350 has a resistivity of about 7.5 kΩ. This results in the comparator 349 comparing the signal voltage 344 with a voltage equal to 7.5/(200+7.5)=3.6% of the voltage across piezoelectric element 338. As described above, in some embodiments, the voltage presented to the first comparator 343 is scaled differently than the voltage presented to the second comparator 349. This difference in scaling ratios can create a band between the first and second comparators where the first comparator will deactivate the first switch but the second comparator will not activate the second switch, and vice versa, such that neither switch is turned on for a certain interval. In some embodiments, the band helps to prevent oscillations that may be created by current overshoot. Current overshoot can occur due to delays introduced by the circuit. For instance, when comparator 343 turns off switch 335, several sources of delay slow this process down. First, distributed capacitance slightly delays the fed back voltage. Next, the comparator 343 has a switching delay time. The FET driver 342 is optically isolated, and this contributes some delay time. Finally, the FET 335 itself also has some delay. This delay—between when the comparator detects that the switch 335 should turn off and when the switch 335 actually does turn off—results in an overshoot current that continues to charge the piezoelectric element 338. Similar delays on the discharge portion of the circuit result in further overshoot. This overshoot can cause oscillations where the charging circuit portion and the discharging circuit portion alternately activate, reducing the accuracy with which the piezoelectric element tracks the signal voltage. Increasing the size of the scaling band can reduce or eliminate the oscillatory overshoot, at the cost of less control over the voltage across the piezoelectric element 338.

In other embodiments, additional methods of creating a band may be employed. For example, in one embodiment, a single set of feedback scaling resistors may be employed as in FIG. 2 and an offset voltage may be added to the signal 44 for comparator 43 or 49. For example, a small positive voltage added to the signal input of comparator 43 or a small negative voltage added to the signal input of comparator 49 can achieve the effects of the two scaling resistors 51 and 50.

In situations where more precise tracking of the signal waveform is desired, derivative feedback can be added to the circuit. Adding a small voltage term to the comparators that is based on the voltage across the capacitor's rate of change makes the circuit somewhat predictive and can compensate for the delays in the control portions of the circuit. FIG. 5 illustrates a circuit that provides derivative feedback to the charging circuit portion and discharging circuit portion during different phases of operation. In the illustrated circuit, diodes 355 and 356 are put in series with resistors 352 and 354, respectively. The diodes 355 and 356 split the derivative feedback voltage into rising feedback and falling feedback, respectively. In this embodiment, when the voltage across the piezoelectric element is rising (i.e. when the source 345 is connected through switch 335) a rising derivative feedback voltage is provided to comparator 343, causing the switch 335 to disconnect earlier. Similarly, when the voltage across the piezoelectric element is falling (i.e. when switch 346 is connected), a falling derivative feedback voltage is provided to comparator 349 causing the switch 346 to disconnect earlier. In a particular embodiment, a capacitance of 347 pF for capacitor 353 and a resistivity of 1350 kΩ for each of resistor 352 and resistor 354 was determined to provide improved derivative feedback across a wide range of different piezoelectric elements.

In some embodiments, a piezoelectric actuated fuel injector is configured to be mechanically biased, for example through the use of mechanical spring, into an open position. In these embodiments, the piezoelectric elements are actuated to close the fuel injector. Accordingly, a high rest voltage is provided to the piezoelectric elements when the there is no signal present to keep the fuel injector closed in its rest state. In further embodiments, the piezoelectric actuating voltage (for example, the source voltage 354 in embodiments employing switching amplifiers as described with respect to FIG. 9) can be modified. For instance, modifying this voltage can change the responsiveness of the piezoelectric elements to the signal voltage or can change the maximum extent of actuation. Such modification may be useful for testing purposes, or may be used in the engine control scheme.

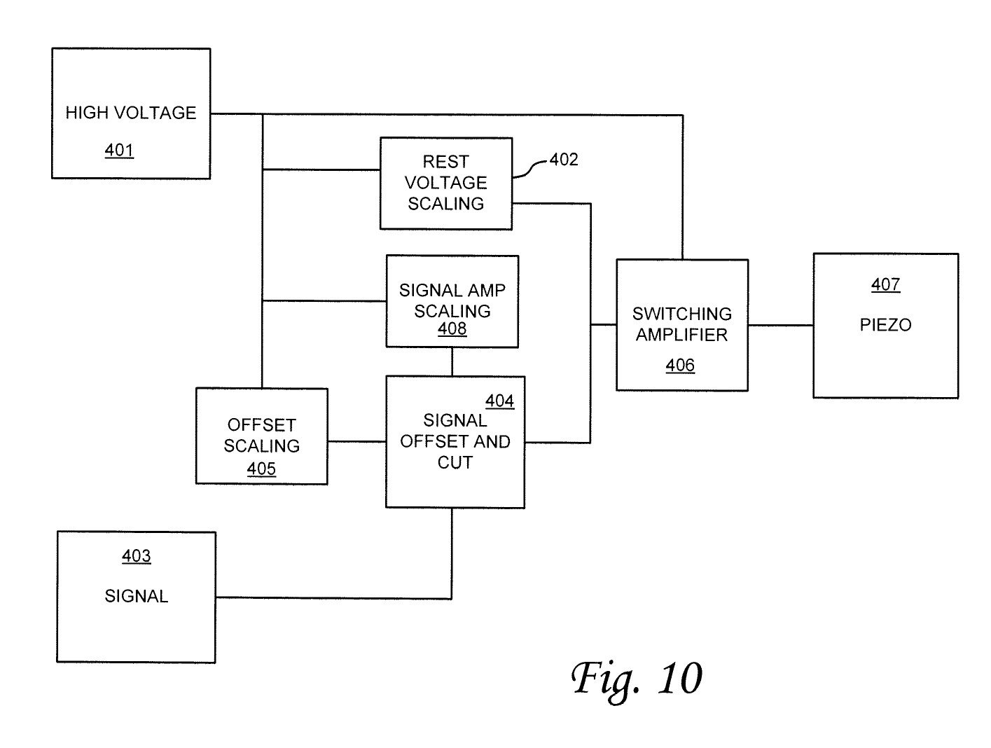

FIG. 10 is a functional block diagram illustrating a configuration that scales system parameters as a high voltage source is modified according to an embodiment of the invention. In the illustrated embodiment, rather than providing independent sources for offset voltages, analog signal voltages, and system rest voltages, these values are made proportional to the high voltage source. FIG. 10 illustrates these changes made to a single piezoelectric channel; similar changes may be made to the remaining piezoelectric channels.

High voltage source 401 is scaled using an offset scaling circuit 405 to provide an offset voltage for use in the offset and cut circuit 404, for example as described with respect to element 208 in FIG. 6A. High voltage source 401 is further scaled by signal amplitude scaling circuit 408 to provide a scaled amplification level for use in the offset and cut circuit 404, for example as described with respect to element 202 in FIG. 6A. Accordingly, when the high voltage source 401 is changed by a certain proportion, the offset point and amplification gain are changed by the same proportion. The signal 403 (for example, from waveform generator 160 described with respect to FIG. 5) is thereby offset, cut, and amplified such that the appropriate portion of the signal 403 continues to drive the piezoelectric element 407.

Furthermore, the rest voltage used by the system is from the high voltage source 401 scaled by rest voltage scaling circuit 402. Accordingly, as the high voltage source 401 is modified by a certain proportion, the rest voltage is scaled by the same proportion. This maintains the operation of switching amplifier 406 with respect to the high voltage source.

In a particular embodiment, during initial system adjustment, the high voltage is set to a nominal value (160V, for example) and the scaling levels of the rest voltage, offset, and analog signal level are all modified for desired operation characteristics. Subsequently, as the high voltage is changed, these parameters scale proportionally.

However, this can change how the divided signal portions act on the piezoelectric elements in embodiments employing multiple signal channels for multiple piezoelectric elements, such as those described with respect to FIGS. 5 and 6. To scale system operation as the high voltage is varied, the rest voltage, as well as the cut point settings and gain settings for each piezoelectric channel, are also changed.

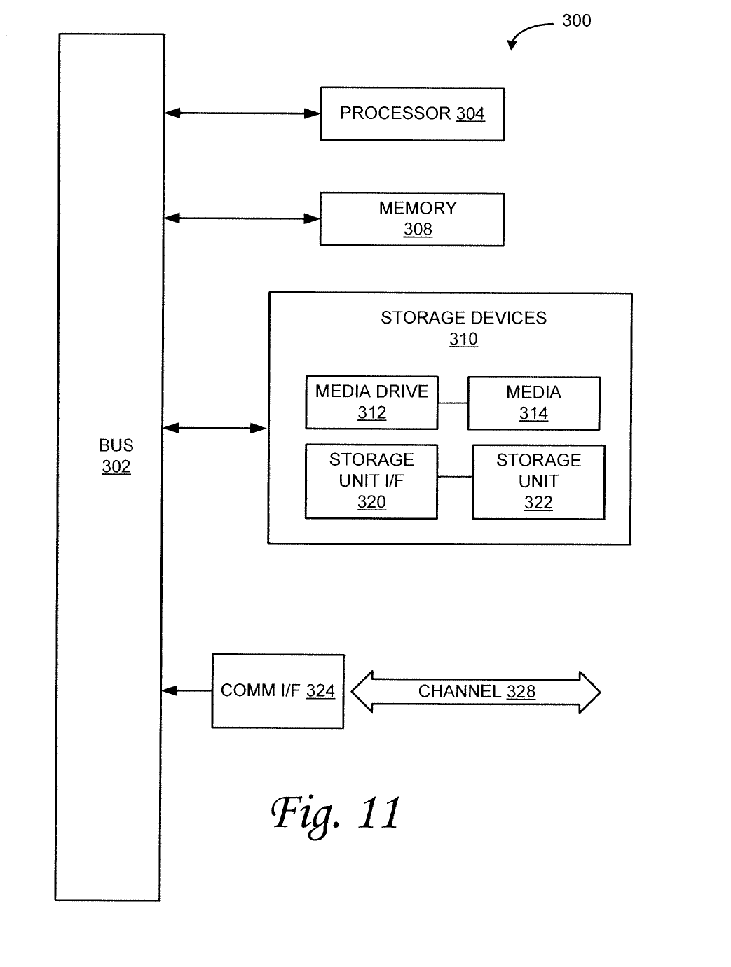

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example-computing module is shown in FIG. 11. Various embodiments are described in terms of this example-computing module 300. After reading this description, it will become apparent to a person skilled in the relevant art how to implement the invention using other computing modules or architectures.

Referring now to FIG. 11, computing module 300 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 300 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 300 might include, for example, one or more processors, controllers, control modules, or other processing devices, such as a processor 304. Processor 304 might be implemented using a general-purpose or special-purpose processing engine such as, for example, a microprocessor, controller, or other control logic. In the example illustrated in FIG. 11, processor 304 is connected to a bus 302, although any communication medium can be used to facilitate interaction with other components of computing module 300 or to communicate externally.

Computing module 300 might also include one or more memory modules, simply referred to herein as main memory 308. For example, preferably random access memory (RAM) or other dynamic memory, might be used for storing information and instructions to be executed by processor 304. Main memory 308 might also be used for storing temporary variables or other intermediate information during execution of instructions to be executed by processor 304. Computing module 300 might likewise include a read only memory (“ROM”) or other static storage device coupled to bus 302 for storing static information and instructions for processor 304.

The computing module 300 might also include one or more various forms of information storage mechanism 310, which might include, for example, a media drive 312 and a storage unit interface 320. The media drive 312 might include a drive or other mechanism to support fixed or removable storage media 314. For example, a hard disk drive, a floppy disk drive, a magnetic tape drive, an optical disk drive, a CD or DVD drive (R or RW), or other removable or fixed media drive might be provided. Accordingly, storage media 314, might include, for example, a hard disk, a floppy disk, magnetic tape, cartridge, optical disk, a CD or DVD, or other fixed or removable medium that is read by, written to or accessed by media drive 312. As these examples illustrate, the storage media 314 can include a computer usable storage medium having stored therein computer software or data.

In alternative embodiments, information storage mechanism 310 might include other similar instrumentalities for allowing computer programs or other instructions or data to be loaded into computing module 300. Such instrumentalities might include, for example, a fixed or removable storage unit 322 and an interface 320. Examples of such storage units 322 and interfaces 320 can include a program cartridge and cartridge interface, a removable memory (for example, a flash memory or other removable memory module) and memory slot, a PCMCIA slot and card, and other fixed or removable storage units 322 and interfaces 320 that allow software and data to be transferred from the storage unit 322 to computing module 300.

Computing module 300 might also include a communications interface 324. Communications interface 324 might be used to allow software and data to be transferred between computing module 300 and external devices. Examples of communications interface 324 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications interface 324 might typically be carried on signals, which can be electronic, electromagnetic (which includes optical) or other signals capable of being exchanged by a given communications interface 324. These signals might be provided to communications interface 324 via a channel 328. This channel 328 might carry signals and might be implemented using a wired or wireless communication medium. These signals can deliver the software and data from memory or other storage medium in one computing system to memory or other storage medium in computing system 300. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to physical storage media such as, for example, memory 308, storage unit 320, and media 314. These and other various forms of computer program media or computer usable media may be involved in storing one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 300 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A method of driving a piezoelectric actuator, comprising:
generating a waveform;
conditioning the waveform to enable operation of a piezoelectric actuator having a plurality of piezoelectric elements; and
transmitting the conditioned waveform to at least one of the piezoelectric elements of the piezoelectric actuator.

2. The method of claim 1, wherein the waveform is configured to enable a predetermined operational behavior of the piezoelectric actuator.

3. The method of claim 2, wherein the waveform is further configured to compensate for physical properties of the piezoelectric actuator.

4. The method of claim 3, wherein the predetermined operational behavior is a substantially constant rate of actuator displacement.

5. The method of claim 1, wherein the step of conditioning comprises isolating portions of the waveform; and wherein the step of transmitting the conditioned waveform comprises transmitting the isolated portions to at least one of the piezoelectric elements of the piezoelectric actuator.

6. The method of claim 5, wherein the step of isolating comprises offsetting the desired waveform by a predetermined offset voltage and clipping the desired waveform at a predetermined clip voltage.

7. The method of claim 5, wherein the step of isolating comprises selectively amplifying a portion of the desired waveform.

8. A piezoelectric driving apparatus, comprising:
a waveform generator to generate a waveform configured to operate a piezoelectric element; and
a plurality of channels coupled to the waveform generator and configured to be electrically coupled to a corresponding plurality of piezoelectric elements of a piezoelectric actuator, wherein a channel comprises:
an input configured to receive a waveform;
a driving amplifier electrically coupled to the input and configured to amplify the waveform; and
an output configured to transmit the waveform and configured to be electrically coupled to a piezoelectric element.

9. The apparatus of claim 8, wherein the waveform is configured to enable a predetermined operational behavior of the piezoelectric actuator.

10. The apparatus of claim 9, wherein the waveform is further configured to compensate for physical properties of the piezoelectric actuator.

11. The apparatus of claim 10, wherein the predetermined operational behavior is a substantially constant rate of actuator displacement.

12. The apparatus of claim 8, further comprising a conditioner electrically coupled to the waveform generator, the conditioner configured to isolate a portion of the waveform and to transmit the isolated portion to at least one of the channels.

13. The apparatus of claim 8, further comprising a switch electrically coupled to the waveform generator and the channels, the switch configured to selectively enable a channel to receive a waveform.

14. The apparatus of claim 13, wherein the waveform generator is one of a plurality of waveform generators and the switch is further configured to selectively determine which waveform generator transmits to which channel.

15. A piezoelectric actuator apparatus, comprising:
a plurality of piezoelectric elements coupled together in series, each piezoelectric element comprising:
a piezoelectric material; and
electrical contacts to allow a voltage to be applied to the piezoelectric material.

16. The apparatus of claim 15, wherein at least one piezoelectric element is configured to operate independently of the other piezoelectric elements.

17. The apparatus of claim 16, further comprising
a waveform generator to generate a waveform configured to operate a piezoelectric element;
a plurality of channels coupled to the waveform generator and coupled to the plurality of piezoelectric elements, wherein a channel comprises:
an input configured to receive a waveform;
a driving amplifier electrically coupled to the input and configured to amplify the waveform; and
an output configured to transmit the waveform and electrically coupled to a piezoelectric element.

18. The apparatus of claim 17, wherein the waveform is configured to enable a predetermined operational behavior of the piezoelectric actuator.

19. The apparatus of claim 18, wherein the waveform is further configured to compensate for physical properties of the piezoelectric actuator.

20. The apparatus of claim 19, wherein the predetermined operational behavior is a substantially constant rate of actuator displacement.

21. The apparatus of claim 17, wherein the piezoelectric driving apparatus further comprises a switch electrically coupled to the waveform generator and the channels, the switch configured to selectively enable a channel to receive a waveform and to selectively determine which waveform generator transmits to which channel.

22. A system, comprising:
a piezoelectric driving apparatus configured to transmit a plurality of waveform signals to a corresponding plurality of piezoelectric elements of a piezoelectric actuator; and
a piezoelectric actuator coupled to the piezoelectric driving apparatus, the piezoelectric driving apparatus comprising:
a waveform generator to generate a waveform configured to operate a piezoelectric element; and
a plurality of channels coupled to the waveform generator and configured to be electrically coupled the piezoelectric elements of the piezoelectric actuator, wherein a channel comprises:
an input configured to receive a waveform;
a driving amplifier electrically coupled to the input and configured to amplify the waveform; and
an output configured to transmit the waveform and configured to be electrically coupled to a piezoelectric element.

23. The system of claim 15, wherein the waveform is configured to enable a predetermined operational behavior of the piezoelectric actuator.

24. The system of claim 23, wherein the waveform is further configured to compensate for physical properties of the piezoelectric actuator.

25. The system of claim 24, wherein the predetermined operational behavior is a substantially constant rate of actuator displacement.

26. The system of claim 15, wherein the piezoelectric driving apparatus further comprises a conditioner electrically coupled to the waveform generator, the conditioner configured to isolate a portion of the waveform and to transmit the isolated portion to at least one of the channels.

27. The system of claim 15, wherein the piezoelectric driving apparatus further comprises a switch electrically coupled to the waveform generator and the channels, the switch configured to selectively enable a channel to receive a waveform and to selectively determine which waveform generator transmits to which channel.
